(19) United States
(12) Patent Application Publication
(10) Pub. No.: US 2005/0012012 A1
(43) Pub. Date: Jan. 20, 2005

(54) Mechanism for elevating an overhead screen

(76) Inventor: Mark Snyders, Coogee (AU)

Correspondence Address: SMITH-HILL AND BEDELL, 12670 N W BARNES ROAD, SUITE 104, PORTLAND, OR, 97229, US

(21) Appl. No.: 10/494,835

(22) PCT Filed: May 20, 2002
(86) PCT No.: PCT/AU02/00607

(30) Foreign Application Priority Data
Nov. 5, 2001 (AU) PR8662

(51) Int. Cl. H05K 5/02

(52) U.S. Cl. 248/345

(57) ABSTRACT

An overhead screen of gull wing profile is supported by a traveller running on a mast extending vertically beside one longitudinal edge of the screen. The upper surface of the screen is attached to three, spaced parallel support tubes and its gull wing profile is maintained by members attached to opposite longitudinal edges of the screen. Tie bars converge inwardly towards the ends of a cross tree at the top of an inclined upper portion of the mast, and the tie bars are pivoted at their ends to the cross trees and to intermediate positions on the outer tubes adjacent the mast and can be raised and lowered by a hand winch on the traveller. The screen is movable from the overhead position illustrated, to a vertical position at which it is lowered and lies alongside the mast with the mast accommodated in the central valley of the gull wing profile of the screen.

### FIELD OF THE INVENTION

THIS INVENTION relates to up-and-over mechanisms. Such mechanisms are widely used on garage doors. They control the movement of the garage door from a first position at which it closes a garage entrance, to a second position at which a car can be driven beneath the elevated horizontal door and into the garage.

### STATE OF THE ART

Up-and-over mechanisms for use with garage doors are positioned at the two side walls of the garage and support the weight of the garage door during the lifting process. There are other applications where an up-and-over mechanism would be useful. For example, for supporting overhead screens in restaurants and for providing car ports. However, such applications do not have parallel side walls to which a garage up-and-over mechanism can be attached and they are typified by having limited space which should be obstructed as little as possible when the screen is in its overhead position. Ideally, the screen should be supported on a single mast and, at least as far as the applicant is aware, a mechanism for supporting a screen during an up-and-over movement and which relies on a single mast and therefore the minimum obstruction of the space beneath and around the screen, has yet to be developed. As a result overhead moveable screening in restaurants has been provided by folding umbrellas which cannot be lowered unless the umbrella canopy is first folded. The canopy cannot therefore have a fixed shape.

### OBJECT OF THE INVENTION

An object of this invention is to provide a novel up-and-over mechanism which relies on a single substantially vertical guide.

### THE INVENTION

In accordance with the present invention a mechanism operates to move a screen of fixed shape from a first position at which the screen is upright and lies alongside a substantially vertical guide with at least one edge extending substantially parallel to the ground, and a second position at which the screen extends overhead and has said one edge extending alongside the guide, such mechanism including: two parallel horizontal pivotal axes, one of which is provided at or adjacent the upper-end portion of the guide and the other of which is provided on the screen and extends parallel to said one edge; a rigid linkage connected at its respective ends to the two pivotal axes to constrain movement of the screen during its displacement between said two positions to a rotational movement about the second of said axes; a traveller connected through an articulation to said one edge and moveable in a controlled manner up-and-down the guide to move the screen between said two positions; and, means for holding the traveller in an elevated position on the mast at which the screen is horizontal and overhead.

### PREFERRED FEATURES OF THE INVENTION

Preferably the guide takes the form of a mast which may be provided by a cylindrical mast. However it may also be provided by a vertical track provided on a wall. The screen is also preferably rectangular in shape and conveniently it is given a gull-wing profile.

The guide is used to support the weight of the screen while it is held in an overhead position. When in the form of a free-standing mast it can provide the minimum amount of obstruction in a restaurant where the screen may be used to shelter diners from the sun so that people can move around freely beneath the screen. The guide may be used in conjunction with a carport, when it is arranged along one side of the carport so that it will not obstruct movement of the car onto a concrete plinth located beneath the screen when in its elevated position. The screen, when lowered, then extends vertically alongside the guide so that the carport is still unobstructed. The guide can be located against one side of the carport conveniently provided by a wall from a neighbouring house, and the wall can then have the guide fixed to it. When used in a restaurant, the screen in its lowered position is capable of providing a visually pleasing partition between groups of diners.

Conveniently the traveller incorporates a winch having an associated cord or winch wire which supports the weight of the traveller from a fixture provided on an upper portion of the guide. The winch may be manually or electrically operated. By rotation of the winch, the traveller can be raised to its elevated position while simultaneously moving the screen from its first position alongside the guide, to its second overhead position. When the guide is provided by a mast, the mast may have its upper portion inclined with respect to the vertical axis of the mast. It may also be mounted so as to rotate about the mast axis. Alternatively the whole mast may be rotated about its base. However it is not essential for the upper portion of the mast to be inclined or cranked with respect to the vertical axis of the rest of the mast, although this does provide advantages when a screen of curved or gull-wire cross-section is used as it enables the guide to be accommodated in the hollow of the screen when it is lowered and vertical.

The linkage is preferably provided by two divergent tie bars which are connected to the horizontal axis at the upper-end portion of the guide and diverge from one another to anchorages provided on the screen and which are spaced from one another by approximately half the length of the screen which corresponds to the length of said edge.

In a preferred arrangement of the invention when a mast is used, the screen is of undulating shape to provide valleys and crests with one of the valleys centred in the middle of the lowered screen. With such an arrangement it is preferred to have the articulation provided by a coiled compression spring or other resilient connection which allows the screen to be moved between its two positions while providing a resilient bias. Such a bias can be arranged to co-operate with the tie bars to provide an over-centre toggle mechanism which permits the screen to lie snugly against the mast with the mast accommodated In the valley of the screen undulation. The toggle mechanism acts to hold the screen in its position against the mast until such times as the screen is to be raised to the overhead position.

### INTRODUCTION TO THE DRAWINGS

The invention will now be described in more detail, by way of example, with reference to the accompanying informal and diagrammatic drawings and photographs in which:—

In the Drawings

FIG. 1 is a greatly simplified diagram of the mechanism and screen as viewed from one side and with the latter in an upper position;

FIG. 2 shows the screen in its lowered position and is a view corresponding to that of FIG. 1;

FIG. 3 is a view perpendicular to FIG. 2 but shows the screen in its lowered position at which it extends vertically alongside a guide provided by a mast;

FIG. 4 is a view of the front of the screen when in its elevated position as seen from the side opposite the mast which is shown partially broken away and to an increased scale with respect to the scale used in FIG. 3;

FIG. 5 is a side view of the upper portion of a guide mast of a second embodiment, a screen supported by the mast being shown in a partially elevated position;

FIG. 6 is a view of the upper portion of a mast as seen from the opposite side of the screen to that shown in FIG. 5, the view being taken partly from beneath the screen, which is shown in its fully elevated position, and from slightly behind the mast;

FIG. 7 shows part of a tie bar extending down to a pivotal anchorage provided on a tube connected to the upper surface of the screen, a link connecting the tie bar to a sliding sleeve on the tube also being shown;

FIG. 8 is a view looking upwardly towards the upper end-portion of the mast;

FIG. 9 is a downward view of part of a hollow cross-beam attached to the central part of the upper surface of the horizontal screen and shows tensioned support wires extending into the beam; and,

FIG. 10 shows parts illustrated in FIG. 9 in the positions they occupy when the screen is lowered to an upright position extending alongside the mast.

### DESCRIPTION OF FIRST EMBODIMENT

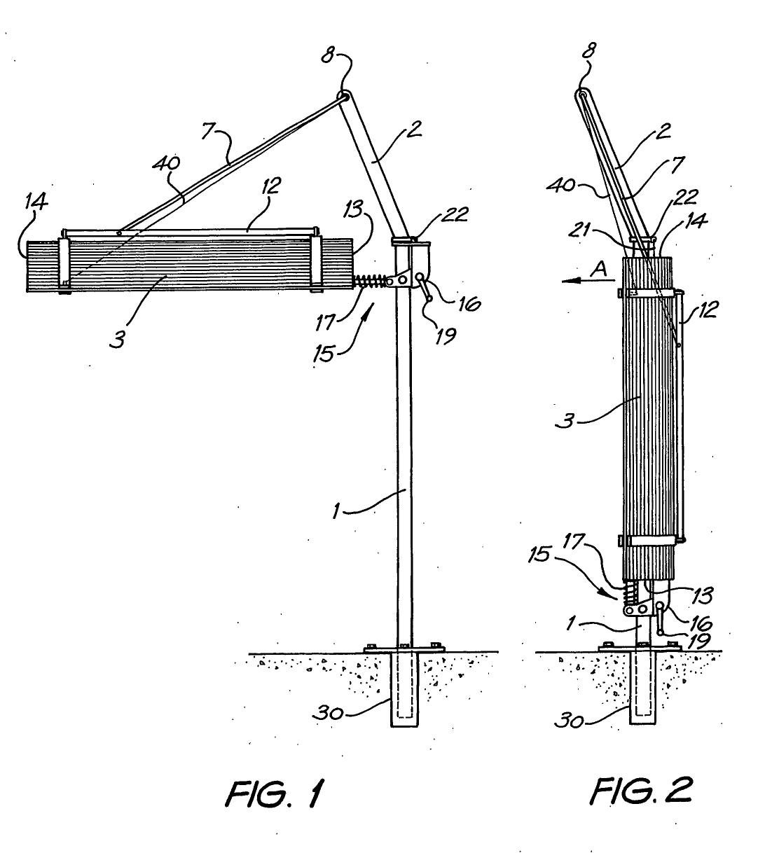

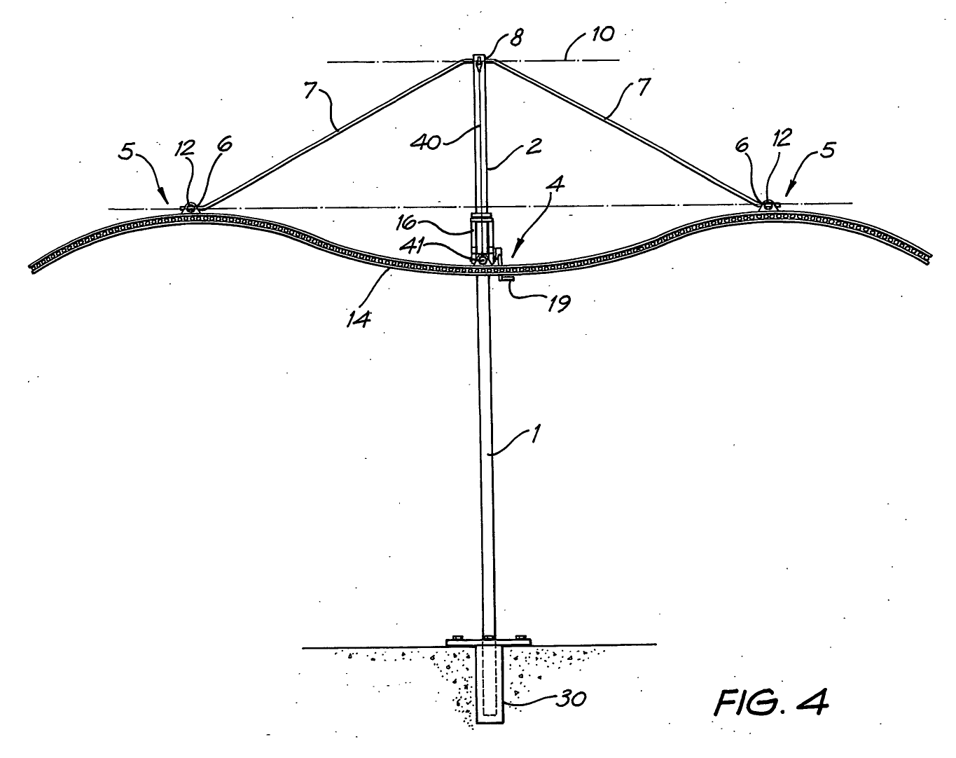

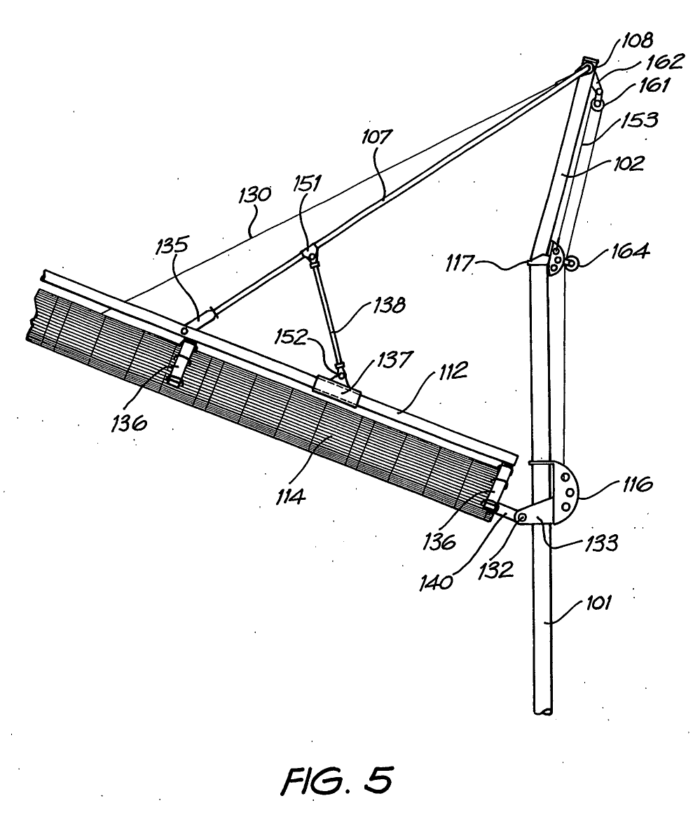

The up-and-over mechanism of FIG. 1 comprises a guide mast 1 provided by a pole and having its upper end 2 inclined slightly so that it extends over the position of a bamboo screen 3. As shown in FIG. 4, the screen is of undulating gull-wing shape providing a valley 4 and two crests 5. Each of the crests 5 is provided with a support tube 12 having an anchorage 6 on its upper surface. Respective tie bars 7 converge from the anchorages 6 to horizontal pivotal connections 8 provided by a cross-tree positioned above the screen at upper the inclined end 2 of the mast 1. The tie bars 7 provide a rigid linkage which is moveable at its ends about two parallel axes 10 and 11 of which the axis 10 is provided by the pivotal connections 8 adjacent the upper end of the mast, and the axis 11 is provided by the two co-axial anchorages 6 which are provided on the respective support tubes 12 fixed to the screen 3. The inclined upper end 2 of the mast is designed to rotate about the mast's vertical axis by the provision of a rotational joint connection (not shown) between the upper end of vertical section of the mast 1 and the base of the upper end 2.

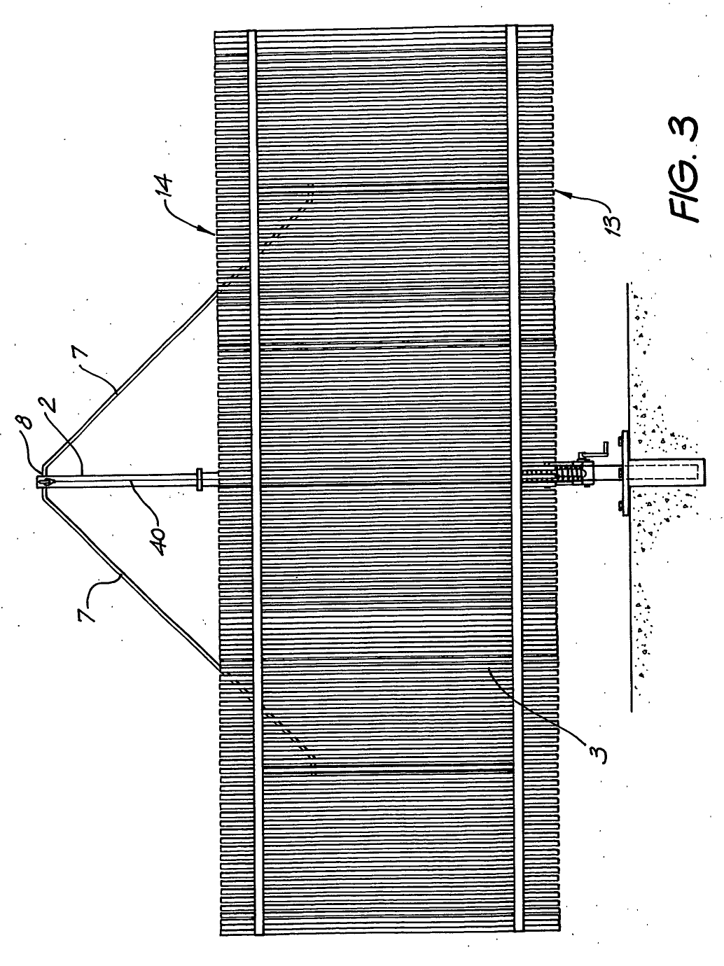

As shown in FIGS. 3 and 4, the screen 3 is of rectangular gull-wing and has two longer side edges 13, 14 extending parallel to the ground. The edge 13 extends beside the mast and is connected by a resilient articulation 15, shown in FIG. 1 and provided by a coiled compression spring 17, to a traveller 16 which is in the form of a bracket vertically slideable along the mast 1 to different vertical positions. The traveller is also rotatable about the vertical axis of the mast 1 by being engaged with a rotational joint connection 22 when at its uppermost position on the mast 1.

The traveller incorporates a winch (not shown) which is manually operated by a handle 19 and has a drum (not shown) around which passes a vertical cord 21 or winch wire. The other end of the cord is attached to a fixture 22 close to the top of the mast so that the traveller 16 can be raised and lowered to different positions on the mast by rotating the winch handle 19. A manually-releasable detent (not shown) associated with a cogged surface of the winch drum, allows the traveller 16 to be locked into any position to which it may be moved. A series of holes (not shown) on the mast and a co-operating cross-pin (not shown) can be used instead for the same purpose.

FIG. 3 shows the screen 3 in its lowered position when it extends vertically alongside the mast 1. It is provided with adjustable telescopic legs (not shown) accommodated in the tubes 12 and which carry, together with the compressed spring 17 the weight of the screen when in its lowered position illustrated. The legs are adjustable in length to suit variations in the ground level beneath the screen, and can be clamped in any adjusted position. When the screen is in its overhead position, the telescopic legs can be manually slid back into their hidden positions in the tubes 12.

It will be noticed from FIG. 2 that the divergent tie bars 7 extend in a plane which crosses the vertical plane of the mast 1 when the screen 3 is in its lowered position. The mast 1 is then accommodated within the valley 4 of the screen 3 and the combination of the tie bars 7 and the spring 17 gives an over-centre toggle device to positively locate the screen 3 in the position shown in FIG. 2 when it lies snugly alongside the mast.

Operation of the First Embodiment

To elevate the screen 3 from the position shown in FIG. 2, its edge 14 is first manually moved in the direction of the other side of the mast, as indicated by the arrow A, such movement being accommodated by rotation of the tie bars 7 about the parallel axes 10, 11 and temporary compression of the spring 17. Once the upper edge 14 of the screen has passed through the vertical plane of the mast 1, the compression spring 17 ceases to be compressed and moves the screen upwardly slightly. The traveller 16 can then be elevated up the mast by operating its winch. This causes the adjacent edge 13 of the screen 3 to rise up the mast and, simultaneously, the tie bars 7 allow the screen 3 to translate from the vertical lowered position shown in FIG. 2, to an elevated horizontal position shown in FIGS. 1 and 4 and at which the screen 3 provides overhead weather protection in order to shield the space beneath it. When the screen 3 is fully elevated, the detent on the traveller 16 is operated to hold it in its upper position. It will be noted that when the traveller 16 is in its upper position, the detent is not accessible to small children because of the height of the traveller 16.

The lower end of the mast 1 is preferably mounted in a socket 30, as shown in FIG. 4. This may be achieved by sinking the lower end of the mast into a cylindrical cup mounted in concrete in the ground.

The above-described, up-and-over mechanism relies on a single substantially vertical guide mast to support the screen and permit it to move from a generally horizontal overhead position arranged on one side of the guide, to a second position at which it is lowered to a vertical position alongside the guide. The screen is preferably made from parallel lengths of bamboo or other lightweight reeds or rods spaced from one another to allow air to pass through it so that vertical air pressures on the screen, when in its elevated position, are minimised while it still provides overhead protection. However the screen may be made of other materials, for example, metal such as aluminium strips. When the screen is made from bamboo rods, the end-portions of the bamboo rods are suitably clamped between pairs of elongated bars which define the undulating pattern of the screen. A clip (not shown) on the guide mast 1 may be used to hold the screen 3 in the position shown in FIGS. 2 and 3.

A short steel cable 40, shown in FIG. 4 may be used to provide additional safety by being attached at its upper end to an adjustment device, such as a butterfly nut or bottle screw (not shown) which can be used to vary the length of the cable in an adjustable manner. The lower end of the cable 40 is attached to a cross-beam 41 fixed to the screen 3 in the central portion thereof and close to the edge 14. The cable 40 absorbs the bulk of the weight of the screen without any further adjustment normally being necessary, when the screen is in its elevated position. When in its lowered position its weight is carried by the legs and the compressed spring 17.

The traveller 16 is provided with a device for preventing its rotation independently of the rotational joint connection 22, when in its upper position. The upper end-portion 2 is able to rotate around the vertical axis of the mast 1 with the rotational joint connection 22. The engagement of the traveller 16 with the fixture 22 also holds the winch detent in its engaged position so that it cannot be unintentionally released. In practice, the traveller 16 may also be equipped with a clamping screw, manually operable, when required, to hold the traveller at a chosen intermediate position on the mast so that it cannot rotate. The mast 1 may be designed to be fully rotational bout its base to enable the screen to be swung arcuately around the mast axis to different positions.

Modifications of First Embodiment

It will be appreciated that the substantially upright guide may be provided by a track formed by a vertical rail fixed to a side wall of a space to be screened from above such as a car port. The traveller then is movable up and down the rail to move the screen between its two positions.

In a further variation of the invention, a series of upright guides may be arranged parallel and spaced from one another, and each guide may be arranged to support a section of screen extending parallel to and alongside all of the guides. The travellers may then be interconnected so that they operate in synchronism so that the screen is moved between its two operating positions by simultaneous operation of the travellers. This can be readily accomplished by using electrical winches on the travellers. Also, where two screens are arranged to cover a space, they can be connected together at their adjacent edges so that the two screens are raised and lowered as one.

Description of Second Embodiment

The embodiment shown in FIGS. 5 to 10 is similar to the embodiment already described but is substantially larger. Where parts correspond to those already referred to by number in FIGS. 1 to 4, the same reference numbering has been used in FIGS. 5 to 10 but in the hundred series.

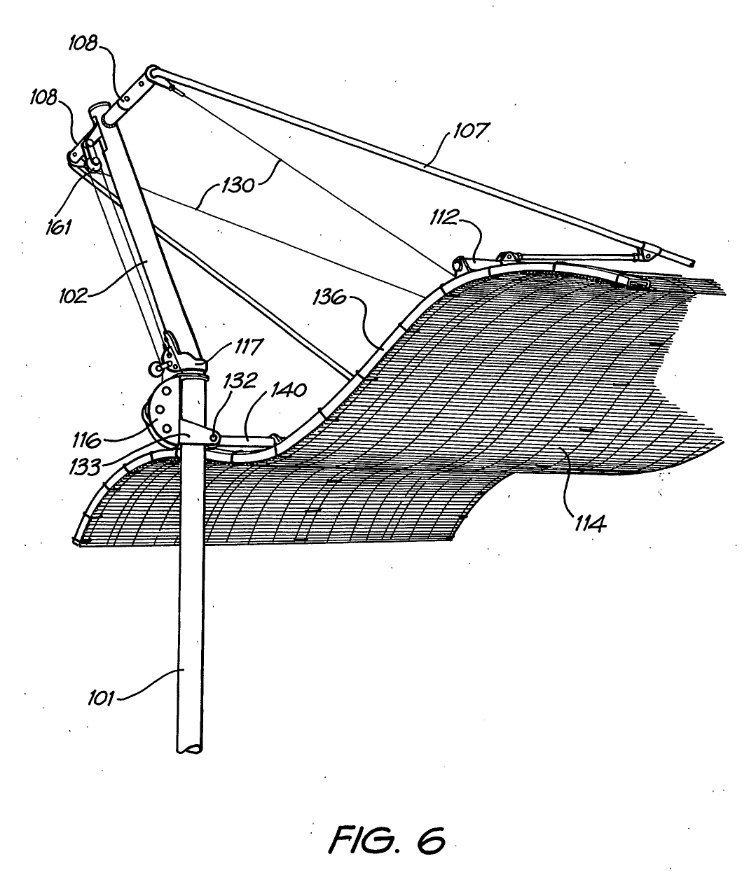

FIGS. 5 and 6 show an overhead platen screen 114 of gull-wing shape supported horizontally by a vertical mast 101 having its lower end bolted to a secure anchorage (not shown) set into a concrete plinth extending at ground level beneath the screen 114.

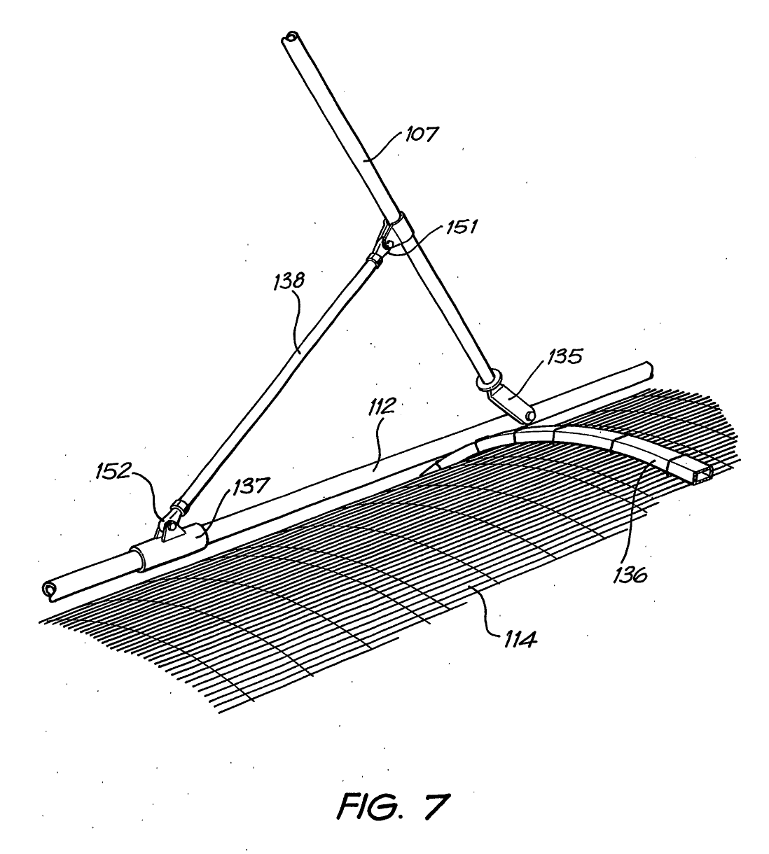

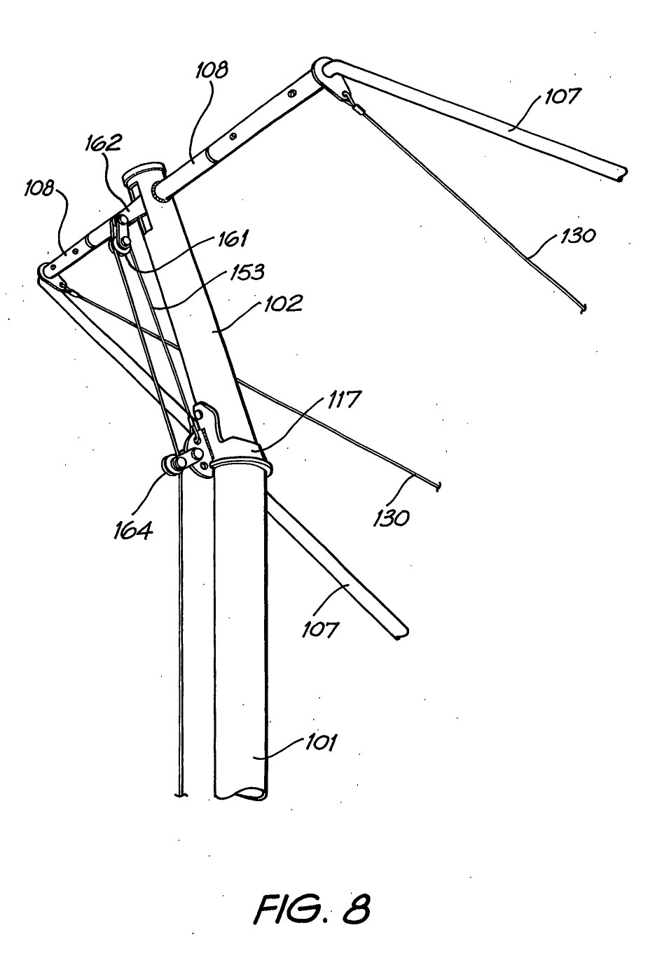

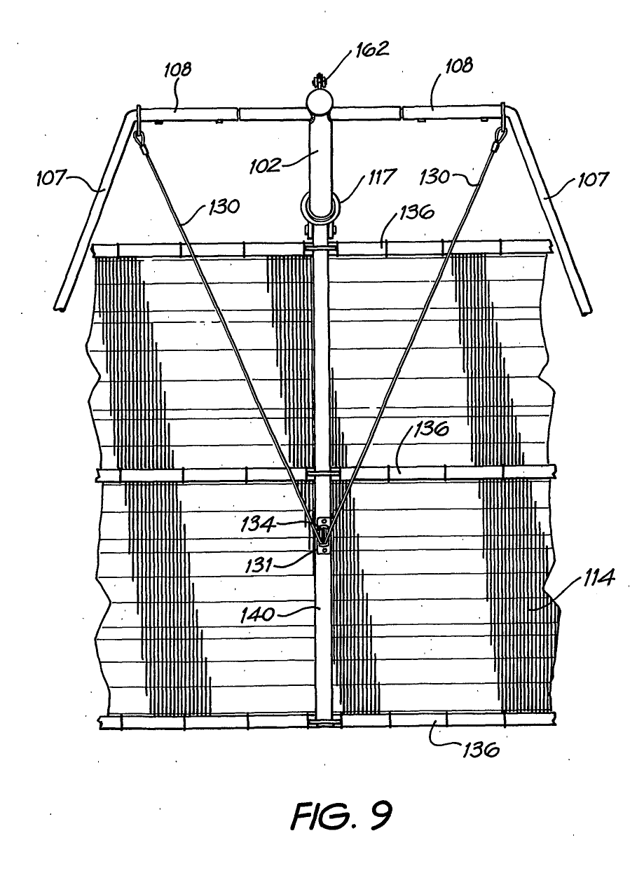

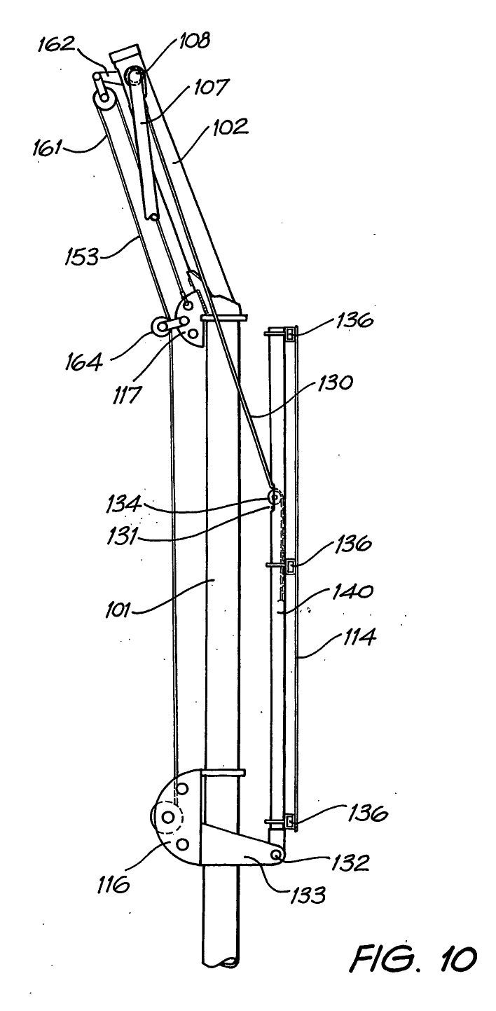

The mast 101 has an upper portion 102 which is rotatable about the vertical axis of the mast 101 and Is connected to its upper end by a rotatable joint 117. Towards its upper end the portion 102 is equipped with a cross-tree 108 from the ends of which two wires 130 converge towards a slot 131 shown in FIG. 9 and formed in a tubular cross-beam 140 adjacent the traveller fixed to the centre of the screen and attached at one end to a traveller 116 able to slide up and down the mast 101. The end of the beam 140 is pivoted at 132 between a pair of parallel lugs 133 embracing the mast 101 and attached to the traveller 116. The two wires 130 pass around respective pulleys 134 located within the Interior of the cross-beam 140 beneath the position of the slot 131. The wires 130 are connected at their free ends, within the cross-beam 140, to one end of a coiled spring (not shown) and an associated moveable weight located inside the interior of the cross-beam 140. The two wires 130 are maintained in tension at all positions of the screen 114, and, when the spring is fully extended the two wires 130 can carry the full weight of the screen if necessary. They also serve, in conjunction with the spring and weight, to damp out undesirable movements of the screen. Normally the two wires 130 only support some of the weight of the overhead screen 114. The remainder of its weight is carried by the traveller 116 and two inextensible divergent tie bars 107 shown more clearly in FIGS. 5, 6 and 8 and which converge towards the respective ends of the cross-tree 108. The tie bars 107 are pivoted at their lower ends to respective support tubes 112 by short lugs 135, as shown in FIG. 7. The two tubes 112 are respectively attached to the centres of the upwardly arched surfaces of the gull-wing screen 114, as is apparent from FIG. 5. The gull-wing shape of the screen 114 is maintained by it being strapped to sinusoidaly shaped formers 136 which are arranged above the two longer edges of the screen 114 and midway between them. The screen is attached to the underside of the formers 136 by spaced plastics straps 118 shown in FIG. 9. Each of the tubes 112 passes through a slideable sleeve 137 shown in FIG. 10, which is connected by a link 138 pivoted at one end 151 to a respective one of the tie bars 107, and at its other end 152 it is pivoted to a respective one of the sleeves 137. The links 138 carry some of the weight of the screen and the sliding movement of the sleeve 137 along the tube 112 acts to dampen too rapid movements of the bars 107 and also allows the associated tie bar 107 to rotate from its position shown in FIG. 6 at which the screen is horizontal and overhead, and its position shown in FIG. 10, at which the screen 114 is close to, but not yet in its vertical position.

A cable 153 is attached at one end to the joint connection 117 between the portion 102 and the mast 101 as shown in FIG. 8. The cable extends upwardly to pass around a pulley 161 attached to a free end of an arm 162 attached to the cross-tree 108 which rotate in the end portion 102. The free end of the arm 162 extends rearwardly through an opening in the end portion 102 as shown in FIG. 8. After passing around the pulley 161, the cable 153 extends down and around a second pulley 164 which guides it vertically down alongside the mast 101 to a winch drum (not shown) on the traveller 116. Thus, the action of rotating the hand winch on the traveller is to haul-in the cable 153 so that the traveller ascends up the mast 101 to the position shown in FIG. 6 at which it abuts the joint 117. Movement of the screen between its overhead horizontal position, and its vertical position is effected by the hand winch on the traveller 116.

Inside the mast end portion 102, the arm 162 has a pivot to which is attached an upper end of a piston (not shown) of an upright pneumatic piston and cylinder until (not shown) mounted inside the mast 101. The pivot is positioned almost directly beneath the rotational axis of the cross-tree 108 when the arm 162 is horizontal. Movement of the arm both upwards and downwards from the horizontal, is thus assisted by the resilient bias of the pneumatic unit which thus acts as an over-centre toggle unit. As the arm 162 is attached to the cross-trees 108, vertical angular movement of the arm 162 from the horizontal produces rotation of the cross-trees 108 through a small angle are in a corresponding direction, such movement being assisted by the bias of the pneumatic unit.

During lowering of the screen 114 from the position shown in FIG. 6 to the position shown in FIG. 10, its weight is carried by the wires 130, the tie bars 107 and the traveller 116. When the traveller 116 reaches its lower-most position, telescopic feet (not shown) extend under gravity from the end portions of the tubes 112 to rest on the ground and absorb the weight of the screen which is now in the position shown in FIG. 10. The tension in the winch cable 153 now slackens and this allows the pneumatic spring bias acting on the arm 162 to move it forcibly into its horizontal position shown in FIG. 8. This is accompanied by a small rotation of the cross-trees 108 in a direction which moves the lower ends of the tie bars 107 rearwards across the vertical plane containing the axis of the mast 101. This causes the upper end of the upright screen 114 to rotate rearwards about its lower end from the position shown in FIG. 10 so that it assumes a truly vertical position with the mast 101 contained within the centre valley of the gull-wing profile of the screen 114. The screen is now in a position similar to that shown In the first embodiment in FIG. 2.

In order to raise the screen from the vertical position to an overhead horizontal position, the winch is operated to cause the traveller 116 to rise up the mast 101. The initial rotation of the winch drum (not shown) tensions the cable 153 and causes the free end of the arm 162 to be pulled downwardly from its upwardly-pointing position, to its downwardly-pointing position. This downward movement of the arm 162 is accompanied by a counter-clockwise rotation of the cross-tree 108 in FIG. 8. This rotation is imparted to the upper ends of the tie bars 107 which therefore displace forwardly at their lower ends to move the upright screen 114 to the position shown in FIG. 10 at which the screen is inclined upwardly away from the front of the mast 101. Further rotation of the winch drum draws in the cable 153, and the traveller progressively rises up the mast together with the attached beam 140, to the position shown in FIG. 6 at which the screen 114 is once again horizontal.

The rotatable connection joint between the upper end of the mast 101 and the inclined portion 102 enables the screen 114 and traveller 116 to be rotated with the portion 102 about the vertical axis of the mast 101 irrespective of the position to which the screen is raised. The screen can therefore be moved to a number of different horizontal positions about the mast axis. At each of these positions it is stably supported by the mechanism described, and can be set at a chosen angle to the horizontal if required.

1-12. (canceled)

13. A mechanism operable to move a screen of fixed shape from a first position at which the screen is upright and lies alongside a substantially vertical guide with at least one edge extending substantially parallel to the ground, and a second position at which the screen extends overhead and has said one edge extending alongside the guide, such mechanism including two parallel horizontal pivotal axes, one of which is provided at or adjacent the upper end portion of the guide and the other of which is provided on the screen and extends parallel to said one edge, a rigid linkage connected at its respective ends to the two pivotal axes to constrain movement of the screen during its displacement between said two positions to a rotational movement about the second of said axes, a traveller connected through an articulation to said edge and movable in a controlled manner up-and-down the guide to move the screen between said two positions; and, means for holding the traveller in an elevated position on the guide at which the screen is horizontal and overhead.

14. A mechanism as set forth in claim 13, in which the guide is provided by an upright mast having its upper end portion rotatable about an upright axis to allow the screen to be turned horizontally about the guide axis to different positions.

15. A mechanism as set forth in claim 13, in which the traveller incorporates a winch having a drum around which passes one end of a cord or wire which extends vertically up the guide to allow rotation of the winch drum to control the vertical position of the traveller on the guide.

16. A mechanism as set forth in claim 13, in which the guide has its upper end portion inclined to the axis of the remainder of the guide the inclined portion being rotatable about the vertical axis of the guide.

17. A mechanism as set forth in claim 13, in which the articulated connection between the traveller and the adjacent side edge of the screen includes a compressible resilient spring which cooperates with the rigid linkage connecting the screen to the guide to provide an over-center toggle device acting to retain the screen positively in a position at which it extends alongside the lower portion of the guide when the screen is in its lowered position.

18. A mechanism as set forth in claim 13, in which the upper end of the guide has a cross tree having pivotal connections to said linkage at their remote ends.

19. A mechanism as set forth in claim 14, in which the screen is of gull wing shape to provide a valley between two crests, and the guide extends upwardly through the valley when the screen is in its lowered position alongside the guide.

20. A mechanism as set forth in claim 15, in which the upper end of the guide has a cross tree having pivotal connections to said linkage at their remote ends, and the cross tree is rotatable in the upper end of the guide and has an arm determining its direction of rotation in accordance with the tension in the cord or wire.

21. A mechanism as set forth in claim 20, in which the movement of the arm is assisted by an over-center toggle provided by a pneumatic piston and cylinder unit and the unit assisting the arm to rock the screen, when lowered to a position at which the guide locates within the central valley of the screen.

22. A mechanism as set forth in claim 13, in which the linkage includes tie bars pivoted at their ends to the upper end of the guide and diverging downwardly towards laterally spaced anchorages provided on rigid tubes attached to the screen, sleeves being slidably mounted on respective tubes and being connected by links to the tie bars associated with the respective tubes.

23. A mechanism as set forth in claim 18, in which two wires extend divergently downwards from respective ends of the cross tree to a central portion of a cross beam extending across the center of the screen and connected to support its weight, the cross beam being connected by a horizontal pivotal axis to the traveller.

24. A mechanism as set forth in claim 23, in which the cross beam is hollow and incorporates a weight and a resilient bias for maintaining the wires in tension when the screen is moved between its vertical and horizontal positions by the traveller.
